(19) United States
(12) Patent Application Publication
(10) Pub. No.: US 2017/0345545 A1
(43) Pub. Date: Nov. 30, 2017

(54) LOW PROFILE POWER INDUCTOR

(71) Applicant: COOPER TECHNOLOGIES COMPANY, Houston, TX (US)

(72) Inventors: Zhuo Min Liu, Dublin, CA (US); Ramdev Kanapady, Campbell, CA (US)

(21) Appl. No.: 15/168,365

(22) Filed: May 31, 2016

(51) Int. Cl. H01F 27/28; H01F 27/24; H05K 1/18

(52) U.S. Cl. CPC H01F 27/28; H05K 1/181; H01F 27/24; H05K 2201/1003

(57) ABSTRACT

An electromagnetic component for a circuit board includes first and second magnetic core pieces and a bifilar coil extending between the first and second magnetic core pieces. The bifilar coil includes a first coil segment having first and second surface mount terminations, and a second coil segment having third and fourth surface mount terminations. The bifilar coil and core pieces facilitate a significant height reduction in the component while offering the same performance as existing power inductor components.

### BACKGROUND OF THE INVENTION

The field of the invention relates generally to electromagnetic components such as inductors, and more particularly to miniaturized, surface mount power inductor components for circuit board applications.

Power inductors are used in power supply management applications and power management circuitry on circuit boards for powering a host of electronic devices, including but not necessarily limited to hand held electronic devices. Power inductors are designed to induce magnetic fields via current flowing through one or more conductive windings, and store energy via the generation of magnetic fields in magnetic cores associated with the windings. Power inductors also return the stored energy to the associated electrical circuit as the current through the winding and may, for example, provide regulated power from rapidly switching power supplies.

Recent trends to produce increasingly powerful, yet smaller electronic devices have led to numerous challenges to the electronics industry. Electronic devices such as smart phones, personal digital assistant (PDA) devices, entertainment devices, and portable computer devices, to name a few, are now widely owned and operated by a large, and growing, population of users. Such devices include an impressive, and rapidly expanding, array of features allowing such devices to interconnect with a plurality of communication networks, including but not limited to the Internet, as well as other electronic devices. Rapid information exchange using wireless communication platforms is possible using such devices, and such devices have become very convenient and popular to business and personal users alike.

For surface mount component manufacturers for circuit board applications required by such electronic devices, the challenge has been to provide increasingly miniaturized components so as to minimize the area occupied on a circuit board by the component (sometimes referred to as the component “footprint”) and also its height measured in a direction parallel to a plane of the circuit board (sometimes referred to as the component “profile”). By decreasing the footprint and profile, the size of the circuit board assemblies for electronic devices can be reduced and/or the component density on the circuit board(s) can be increased, which allows for reductions in size of the electronic device itself or increased capabilities of a device with comparable size. Miniaturizing electronic components in a cost effective manner has introduced a number of practical challenges to electronic component manufacturers in a highly competitive marketplace. Because of the high volume of components needed for electronic devices in great demand, cost reduction in fabricating components has been of great practical interest to electronic component manufacturers.

In order to meet increasing demand for electronic devices, especially hand held devices, each generation of electronic devices need to be not only smaller, but offer increased functional features and capabilities. As a result, the electronic devices must be increasingly powerful devices. For some types of components, such as magnetic components that provide energy storage and regulation capabilities, meeting increased power demands while continuing to reduce the size of components that are already quite small, has proven challenging.

### BRIEF DESCRIPTION OF THE DRAWINGS

Non-limiting and non-exhaustive embodiments are described with reference to the following Figures, wherein like reference numerals refer to like parts throughout the various drawings unless otherwise specified.

FIG. 1 is a perspective view of an exemplary reference power inductor for a circuit board.

FIG. 2 is an exploded view of an exemplary low profile power inductor for a circuit board according to an embodiment of the present invention.

FIG. 3 is a perspective view of a first core piece for the power inductor shown in FIG. 2.

FIG. 4 is a perspective view of a second core piece for the power inductor shown in FIG. 2.

FIG. 5 is a perspective view of a first exemplary coil segment for the power inductor shown in FIG. 2.

FIG. 6 is a perspective view of a second exemplary coil segment for the power inductor shown in FIG. 2.

FIG. 7 is a first perspective assembly view of the power inductor shown in FIG. 2.

FIG. 8 is a second perspective assembly view of the power inductor shown in FIG. 2

### DETAILED DESCRIPTION OF THE INVENTION

Exemplary embodiments of inventive electromagnetic inductor component assemblies and constructions are described below for higher current and power applications having low profiles that are difficult, if not impossible, to achieve, using conventional techniques. Electromagnetic components and devices such as power inductors components may also be fabricated with reduced cost compared to other known miniaturized power inductor constructions. Manufacturing methodology and steps associated with the devices described are in part apparent and in part specifically described below but are believed to be well within the purview of those in the art without further explanation.

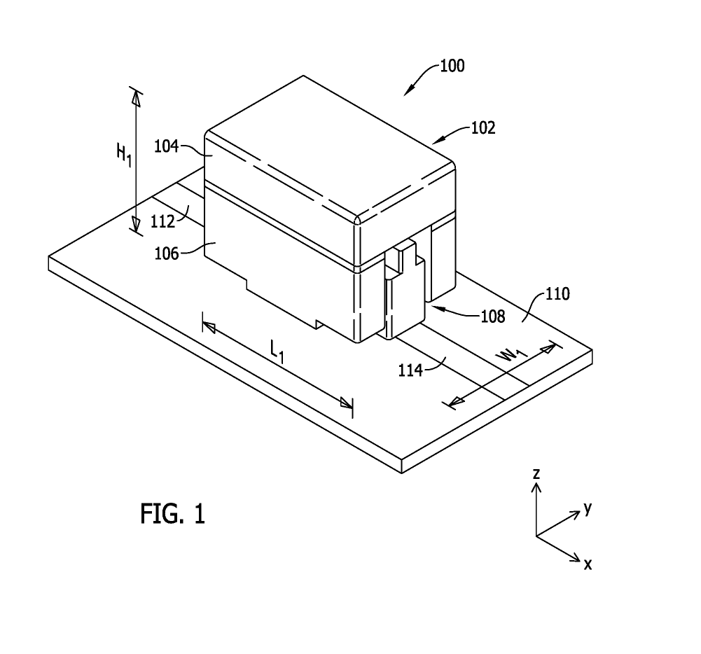

FIG. 1 is a top perspective view of a first exemplary embodiment of a surface mount, electromagnetic component 100 that is configured as a power inductor component, although other types of electromagnetic components may benefit from the teachings described below, including but not limited to inductor components other than power inductors, and also including transformer components.

As shown in FIG. 1, the component 100 generally includes a magnetic core 102 defined by a first core piece 104 and a second core piece 106. A coil winding 108 is partly contained in respective portions of each of the first and second core pieces 104, 106 and includes flat, surface mount terminals for establishing electrical connection with a circuit board 110. In combination, the core pieces 104, 106 impart on overall length L₁ of the magnetic core 102 along a first dimension such as an x axis of a Cartesian coordinate system. Each core piece 104, 106 also has a width W₁ measured along a second dimension perpendicular to the first axis such as a y axis of a Cartesian coordinate system, and a height H₁ measured along a third dimension perpendicular to the first and second axis such as a z axis of a Cartesian coordinate system. In the example shown in FIG. 1, the dimension L₁ of the component 100 is about 10 mm, the dimension W₁ is about 7 mm, and the dimension H₁ is about 10 mm.

The component 100 capably handles higher current, higher power applications beyond the limits of conventional electromagnetic component constructions, and is suitable for use as a power inductor when surface mounted to the circuit board 110 via conductive circuit traces 112, 114 utilizing for example, known soldering techniques. The component 100 shown has an exemplary open circuit inductance (OCL) of about 330 nH, a direct current resistance (DCR) of about 0.185 mΩ, and a saturation current Iₛₐₜ of about 30 A, 20% roll off. Relative to conventional power inductors having similar performance, the component 100 is rather low profile in the height dimension. Further reduction in the component profile is desired, however, although doing so without affecting the performance of the component presents practical challenges and has until now been elusive.

For the sake of the present description, the power inductor component 100 is referred to herein as a reference component having the dimensions L₁, W₁, and H₁ and the exemplary OCL, DCR and Iₛₐₜ values above. The challenge to further reduce the profile (the H₁ dimension) of the component 100 while providing similar dimensions W₁, and H₁ (i.e., about the same footprint of the component on the board 100) and similar exemplary OCL, DCR and Iₛₐₜ values is met by an exemplary embodiment of the present invention as described below. Further space savings and reductions in size of circuit board assemblies and associated devices are accordingly realized without compromising the performance of the component.

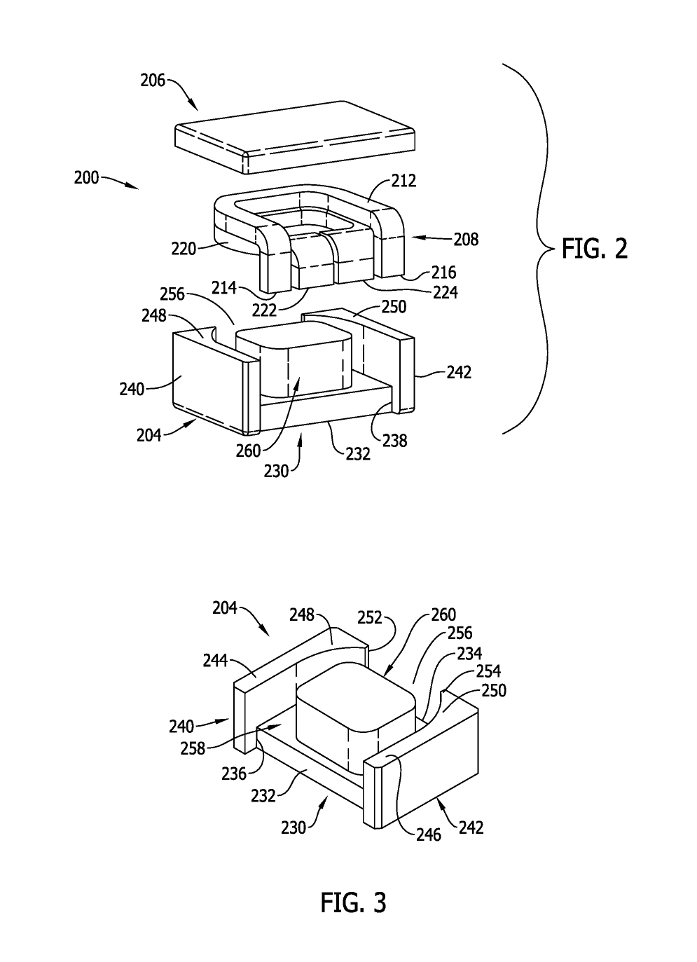

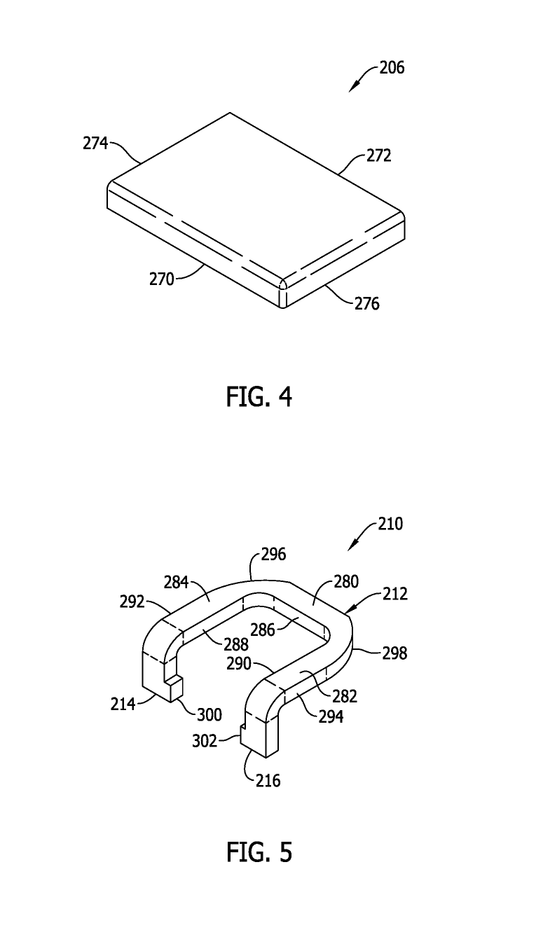

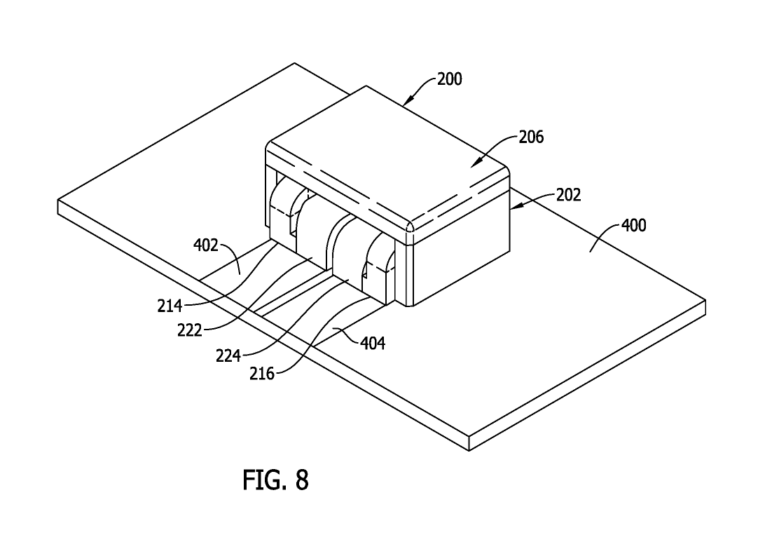

FIG. 2 shows an electromagnetic component assembly 200 formed in accordance with an exemplary embodiment of the present invention in exploded view, and FIGS. 7 and 8 show the electromagnetic component assembly 200 in assembled form. The component assembly 200 includes a magnetic body 202 fabricated from a first magnetic core piece 204 (shown separately in FIG. 3), a second magnetic core piece 206 (shown separately in FIG. 4) and a bifilar coil 208 extending between the first and second magnetic core pieces 204 and 206.

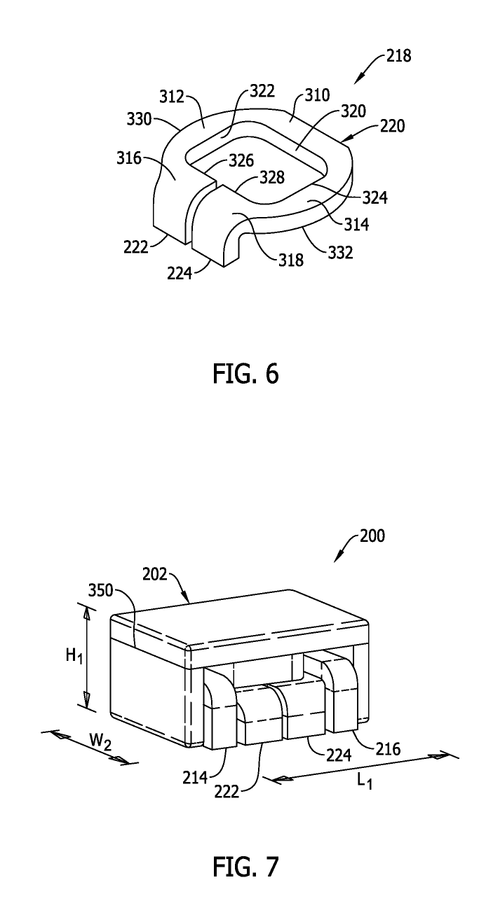

The bifilar coil 208 includes a first coil segment 210 (shown separately in FIG. 5) including a first planar coil winding 212 and first and second surface mount terminations 214 and 216, and a second coil segment 218 (shown separately in FIG. 6) including a second planar coil winding 220 and third and fourth surface mount terminations 222 and 224. The bifilar coil 208 facilitates a significant reduction in the profile of the component assembly 200 relative to the component assembly 100, and the core pieces 204, 206 facilitate a relatively simple and economical construction of the component assembly 200.

The first core piece 204 and the second core piece 206 are each formed and fabricated from ferrite material or soft magnetic particle materials utilizing known techniques such as molding of granular magnetic particles to produce the desired shape such as the example shapes shown in the Figures and described further below. Soft magnetic powder particles used to fabricate the core pieces 204, 206 may include Ferrite particles, Iron (Fe) particles, Sendust (Fe—Si—Al) particles, MPP (Ni—Mo—Fe) particles, HighFlux (Ni—Fe) particles, Megaflux (Fe—Si Alloy) particles, iron-based amorphous powder particles, cobalt-based amorphous powder particles, and other suitable materials known in the art. Combinations of such magnetic powder particle materials may also be utilized if desired. The magnetic powder particles may be obtained using known methods and techniques. Optionally, the magnetic powder particles may be coated with an insulating material such that the core pieces 204, 206 may possess so-called distributed gap properties to facilitate energy storage in a power inductor application. A physical gap may also be provided in the magnetic body 202 as described below for energy storage purposes of a power inductor.

The first core piece 204 (FIGS. 2 and 3) generally includes a flat and planar base 230 having a generally rectangular shape. The base in the example shown includes a first longitudinal side edge 232, a second longitudinal side edge 234 opposing the first longitudinal side edge 232, a first lateral side edge 236 (FIG. 3) and a second lateral side edge 238 (FIG. 2) opposing the first lateral side edge 234. The side edges 232, 234, 236, 238 are arranged generally orthogonally to one another.

The first core piece 204 also includes upstanding lateral side walls 240, 242 opposing one another on the lateral side edges 236, 238 of the base 220. The lateral side walls 240, 242 extend above the base 220 and define an opening therebetween that is shaped and dimensioned to receive the bifilar coil 208 as described further below. In the example shown, each lateral side wall 240, 242 also includes a respective straight portion 244, 246 and a curved portion 248, 250. The curved portions 248, 250 curve in an inward direction such that the respective ends 252, 254 of the curved portions 248, 250 generally face one another. The ends 252, 254 of the curved portions 248 are spaced apart from one another, however, defining a first opening 256 above the longitudinal side edge 234 of the base 220. On longitudinal side 232 of the base 220, the straight portions 244, 246 of the lateral side walls 240, 242 define a second opening 258 above the longitudinal side edge 232 of the base 220. The opening 258 is seen to be larger than the opening 256. The longitudinal side edge 232 of the base 220 is also recessed relative to the end edges of the lateral side walls 240, 242, and the recess defines a space to receive the surface mount terminations 214, 216, 222, 224 when the component is assembled.

The first core piece 204 also includes a guide protection 260 extending between the lateral side walls 240, 242 and above the base 220. The guide protection 260 facilitates assembly of the bifilar coil 208 as well as provides additional magnetic core area inside the bifilar coil 208 for enhanced performance. In the example shown, the guide protection 260 is generally rectangular in profile with rounded corners. Further, the guide projection is nearly square in the embodiment depicted, with the lateral sides (the sides parallel to the straight portions 244, 246 of the lateral side walls 240, 242) of the projection 260 being about 1 mm shorter than the longitudinal sides of the projection 260. The guide protection 260 further has rounded corners where the lateral sides longitudinal sides of the projection meet.

The second core piece 206 (FIGS. 2 and 4) is formed and fabricated as a generally flat and planar element with a generally rectangular shape as shown. Similar to the base 220 of the core piece 204, the core piece 206 includes a first longitudinal side edge 270, a second longitudinal side edge 272 opposing the first longitudinal side edge 270, a first lateral side edge 274 and a second lateral side edge 276 opposing the first lateral side edge 274. The side edges 270, 272, 274, 276 are arranged generally orthogonally to one another. The second core piece 206, unlike the asymmetrical core piece 204, is a symmetrical plate-like element. It is recognized, however, that the exemplary core shapes described are exemplary only, and that in another embodiment the core pieces may be similarly shaped to one another, whether in an asymmetrical or symmetrical shape.

Referring now to FIG. 5, the first coil segment 210 of the bifilar coil 208 includes the first planar coil winding 212 extending as a U-shaped element having a first portion 280 extending generally linearly, and two portions 282, 284 extending in spaced apart but generally parallel orientation to one another from the respective ends of the first portion 280. The first planar coil winding 212 further includes an inner periphery defined by edges 286, 288, 290 and rounded transitions therebetween that are complementary in shape and dimension to the guide projection 260 in the first core piece 204. As such, the inner periphery edges 286, 288, 290 may be received over the respective side edges of the guide projection 260 with a desired orientation. The first planar coil winding 212 further includes an outer periphery defined by straight edges 292, 294 and curved edges 296, 298 that are complementary in shape and dimension to the straight portions 244, 246 and the curved portions 248, 250 on the inner periphery of the lateral side walls 240, 242 of the core piece 204. By virtue of the complementary straight and curved edges of the first core piece 204 and the outer periphery of the of the first planar coil winding 212 the first coil segment 210 can only be assembled with the core piece 204 when the straight and curved portions are properly aligned.

The surface mount terminations 214, 216 in the example shown are formed integrally with the first planar coil winding 212, and extend in a substantially perpendicular relation to the plane of the first planar coil winding 212. As such, in the example shown, the first planar coil winding 212 extends in a generally horizontal plane, while the surface mount terminations 214, 216 extend in a generally vertical plane. The surface mount terminations 214, 216 also include inwardly facing tabs 300, 302 that impart an L-shape appearance to the surface mount terminations 214, 216. The tabs 300, 302 provide an enlarged surface area on the bottom of the terminations 214, 216 for mounting to a circuit board 400 (FIG. 8).

Referring now to FIG. 6, the second coil segment 218 of the bifilar coil 208 includes the second planar coil winding 220 extending as a U-shaped element having a first portion 310 extending generally linearly, and two portions 312, 314 extending in spaced apart but generally parallel orientation to one another from the respective ends of the first portion 310. At the distal ends of each portion 312, 314 opposite the portion 310, the second coil segment 218 includes inwardly depending portions 316, 318 from which the surface mount terminations 222, 224 depend. The depending portion 316, 318 in combination define a fourth side of the second coil segment 218, in contrast to the first coil segment 218 that has only three sides as shown in FIG. 5.

The second planar coil winding 220 further includes an inner periphery defined by edges 320, 322, 324, 326, 328 and rounded transitions therebetween that are complementary in shape and dimension to the guide projection 260 in the first core piece 204. As such, the inner periphery edges 320, 322, 324, 326, 328 may be received over the respective side edges of the guide projection 260 with a desired orientation. The second planar coil winding 220 further includes an outer periphery defined by curved edges 330, 332 that are complementary in shape and dimension to the curved portions 248, 250 on the inner periphery of the lateral side walls 240, 242 of the first core piece 204. By virtue of the curved edges of the first core piece 204 and the outer periphery of the of the first planar coil winding 212 the first coil segment 210 can only be assembled with the core piece 204 when the straight and curved portions are properly aligned.

The surface mount terminations 222, 224 in the example shown are formed integrally with the second planar coil winding 220, and extend in a substantially perpendicular relation to the plane of the second planar coil winding 220. As such, in the example shown, the second planar coil winding 220 extends in a generally horizontal plane, while the surface mount terminations 222, 224 extend in a generally vertical plane. Compared to the coil segment 210 (FIG. 5) the terminations 222, 224 of the second planar coil winding 220 are only slightly spaced from one another. Also comparing the coil segment 210 and 218, the outer peripheries of the planar coil windings 212, 220 are different.

The bifilar coil 208 including the coil segments 210, 218 described above are sometimes referred to as a preformed coil having preformed coil segments. As seen in FIGS. 2, 5 and 6, the coil segments 210, 218 may be fabricated from a sheet of electrical conductive material or conductive metal alloy that is stamped or otherwise formed into the exemplary shapes shown and described. The preformed coil segments 210, 218 are distinguished from a coil winding that is bent, shaped or otherwise formed over or around the outer surfaces of a core piece to its final shape as the component is fabricated. Preformed coil segments are advantageous because bending or shaping the coils around the outer surfaces of a core piece can crack the relatively fragile core pieces and compromise the performance and reliability of the constructed devices. This is particularly so as the core pieces become increasingly miniaturized to meet the needs of modern electronic devices. Preforming of the bifilar coil 208 is advantageous in other aspects as well. In particularly, the preformed bifilar coil 208 may be separately formed and fabricated from the core pieces 204 and 206 and may be provided for final assembly without having to further shape of any of the component parts, reducing or eliminating assembly steps and process that non-preformed coils entail.

When assembled to the first core piece 204 to complete the bifilar coil 208, the second planar coil winding 220 of the coil segment 218 is first applied to the first core piece 204 by fitting the inner periphery of the second planar coil winding 220 over the complementary side surfaces of the guide projection 260 of the first core piece 204. The second planar coil winding 220 generally seats upon the base 230 of the first core piece 204, and the surface mount terminations 222, 224 extend over the side edge 232 of the base 230 of the first core piece 204 as seen in FIGS. 2, 7 and 8.

Once the second planar coil winding 220 is in place on the first core piece 204, the first planar coil winding 212 of the coil segment 210 is applied to the first core piece 204 by fitting the inner periphery of the first planar coil winding 212 over the complementary side surfaces of the guide projection 260 of the first core piece 204. The first planar coil winding 210 generally seats upon and overlies the second planar coil winding 220. The surface mount terminations 214, 216 extend over the side edge 232 of the base 230 of the first core piece 204 as seen in FIGS. 2, 7 and 8. As such, the inner peripheries of the first and second planar coil windings 212, 220 are aligned with one another about the guide projection 260 of the first core piece 204.

Optionally, instead of the assembly described above, the first and second coil segments 212, 218 may be assembled to one another first and then collectively inserted over the guide projection 160 of the first core piece 204. The first and second coil segments 212, 218 can also be bonded to one another before assembly to the core piece 204 or after assembly to the core piece 204 in different embodiments.

The first surface mount termination 214, second surface mount termination 216, third surface mount termination 222 and fourth surface mount termination 224 all extend on the first side edge of the first magnetic core piece 204 as shown once the bifilar coil 208 is assembled. The third and fourth surface mount terminations 222, 224 are in between the first and second surface mount terminations 214, 216. The third and fourth surface mount terminations 222, 224 are also offset from the first and second surface mount terminations 214, 216 in the example shown. That is, the third and fourth surface mount terminations 222, 224 extend farther from the first core piece 204 on the first side edge 232 than do the first and second surface mount terminations 214, 216. A portion of the bifilar coil 208 is exposed on the back side of the first core piece 206 via the opening 256 (FIGS. 2 and 4).

The second core piece 206 is then assembled over the first core piece 204 to complete the assembly of the component 200. The second core piece 206 sits on top of the first core piece 204. A gap or space is created between the second coil segment 212 and the first core piece 204 in the assembly. Also, a physical gap 350 may be established between the core pieces 204, 206. The gap 350 may be accomplished, for example, by making the height of the center guide projection 260 slightly larger than the height of the lateral side walls 240, 242 of the first core piece 204. Other variations of physical gaps are possible in other embodiments any may be optionally employed as well. The physical gaps facilitate energy storage in the component 200, such that the component 200 is a suitable power inductor in contemplated embodiments. The core pieces 204, 206 and the bifilar coil 208 may be bonded in place in any known manner to complete the component fabrication.

Once the component 200 is fully assembled it may be mounted to the circuit board 400 as shown in FIG. 8. The first surface mount termination 214 and the third surface mount termination 222 are each connected to a first circuit trace 402 on the circuit board 400, while the second surface mount termination 216 and the fourth surface mount termination 224 are each connected to a second circuit trace 404 on the circuit board 400. The first coil segment 212 and the second coil segment 220 are therefore electrically connected in parallel inside the first core piece 204. The bifilar coil 208 and the coil segments 212, 214 in combination complete a single turn of an inductor winding inside the first core piece 204. Because of the relative size of the coil segments in the x, y plane of the circuit board 400, the bifilar coil 208 provides ample inductance to the component 100 in use.

Like the component 100 (FIG. 1) the component 200 capably handles higher current, higher power applications beyond the limits of conventional electromagnetic component constructions, and is suitable for use as a power inductor when mounted to the circuit board 400 in a known manner.

The component 200 shown and described in one contemplate embodiment has a dimension L₁ of about 10 mm, the dimension W₂ is about 7.5 mm, and the dimension H₂ is about 4.94 mm. has an exemplary open circuit inductance (OCL) of about 327 nH, a direct current resistance (DCR) of about 0.185 mΩ, and a saturation current Iₛₐₜ of about 30 A, 23.7% roll off. By comparison to the component 100 (FIG. 1) these parameters are nearly identical as shown in Table 1 below.

TABLE 1

| Component | Length | Width | Height | OCL | DCR | Iₛₐₜ |
|---|---|---|---|---|---|---|
| 100 | 10 mm | 7 mm | 10 mm | 330 nH | 0.185 mΩ | 30 A |
| 200 | 10 mm | 7.5 mm | 4.94 mm | 327 nH | 0.185 mΩ | 30 A |

Significantly, and as also seen in Table 1, the component 200 is much lower profile in the height dimension relative to the component 100. The component 200 has a nearly identical length and width dimension to the component 100 (FIG. 1), but a height dimension that is more than 50% less, while otherwise offering equal performance to the component 100. The component 200 is manufacturable at relatively low cost with high reliability by virtue of the construction described above.

The benefits and advantages of the inventive concepts disclosed are now believed to have been amply demonstrated in view of the exemplary embodiments disclosed.

An electromagnetic component for a circuit board has been disclosed including a first magnetic core piece, a second magnetic core piece, and a bifilar coil extending between the first and second magnetic core pieces, wherein the bifilar coil comprises a first coil segment including first and second surface mount terminations, and a second coil segment including the third and fourth surface mount terminations.

Optionally, the first, second, third and fourth surface mount terminations may extend on a first side edge of the first magnetic core piece. The first magnetic core piece may include a second side edge opposing the first side edge, and the second side edge may expose a portion of the bifilar coil. The third and fourth surface mount terminations may be located between the first and second surface mount terminations. The third and fourth surface mount terminations may be offset from the first and second surface mount terminations.

As further options, the first coil segment may include a first planar coil winding and the second coil segment includes a second planar coil winding, with the first coil segment overlying the second coil segment. The first planar coil winding may define a first inner periphery, and the second planar coil winding may define a second inner periphery, with the first inner periphery aligning with the second inner periphery. The first magnetic core piece may include a guide protection, the guide projection having an outer periphery, and the aligned first and second inner peripheries being received over the outer periphery of the guide projection. The second magnetic core piece may be generally planar. The first planar coil winding may define a first outer periphery, and the second planar coil winding may define a second outer periphery, with the first outer periphery being different from the second outer periphery.

The electromagnetic component of claim 1 may be in combination with the circuit board, wherein the first coil segment and the second coil segment are electrically connected in parallel.

The first magnetic core piece may optionally include opposing side walls, each of the opposing side walls including a straight section and a curved section. The curved section of each of the first and second opposing side walls may be curved inwardly toward one another. The first magnetic core piece and the second magnetic core piece may be differently shaped from one another. The first magnetic core piece may be symmetrical and the second magnetic core piece is asymmetrical.

The bifilar coil may complete a single turn of an inductor winding. The bifilar coil may be preformed from the first and second magnetic core pieces. The first, second, third and fourth surface mount terminations may be formed integrally with the bifilar coil. The component may have a height dimension of less than about 5 mm. The component may be a power inductor.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An electromagnetic component for a circuit board comprising:
a first magnetic core piece;
a second magnetic core piece; and
a bifilar coil extending between the first and second magnetic core pieces, wherein the bifilar coil comprises a first coil segment including first and second surface mount terminations and a second coil segment including third and fourth surface mount terminations.

2. The electromagnetic component of claim 1, wherein the first, second, third and fourth surface mount terminations extend on a first side edge of the first magnetic core piece.

3. The electromagnetic component of claim 2, wherein the first magnetic core piece comprises a second side edge opposing the first side edge, and the second side edge exposing a portion of the bifilar coil,

4. The electromagnetic component of claim 2, wherein the third and fourth surface mount terminations are located between the first and second surface mount terminations.

5. The electromagnetic component of claim 2, wherein the third and fourth surface mount terminations are offset from the first and second surface mount terminations.

6. The electromagnetic component of claim 1, wherein the first coil segment includes a first planar coil winding and the second coil segment includes a second planar coil winding, the first planar coil winding overlying the second planar coil winding.

7. The electromagnetic component of claim 6, wherein the first planar coil winding defines a first inner periphery, and the second planar coil winding defines a second inner periphery, the first inner periphery aligning with the second inner periphery.

8. The electromagnetic component of claim 7, wherein the first magnetic core piece comprises a guide protection, the guide projection having an outer periphery, the aligned first and second inner peripheries being received over the outer periphery of the guide projection.

9. The electromagnetic component of claim 8, wherein the second magnetic core piece is generally planar.

10. The electromagnetic component of claim 6, wherein the first planar coil winding defines a first outer periphery, and the second planar coil winding defines a second outer periphery, the first outer periphery being different from the second outer periphery.

11. The electromagnetic component of claim 1, in combination with the circuit board, and wherein the first coil segment and the second coil segment are electrically connected in parallel.

12. The electromagnetic component of claim 1, wherein the first magnetic core piece comprises opposing side walls, each of the opposing side walls including a straight section and a curved section.

13. The electromagnetic component of claim 11, wherein the curved section of each of the first and second opposing side walls is curved inwardly toward one another.

14. The electromagnetic component of claim 1, wherein the first magnetic core piece and the second magnetic core piece are differently shaped from one another.

15. The electromagnetic component of claim 1, wherein the first magnetic core piece is symmetrical and wherein the second magnetic core piece is asymmetrical.

16. The electromagnetic component of claim 1, wherein the bifilar coil completes a single turn of an inductor winding.

17. The electromagnetic component of claim 1, wherein the bifilar coil is preformed from the first and second magnetic core pieces.

18. The electromagnetic component of claim 17, wherein the first, second, third and fourth surface mount terminations are formed integrally with the bifilar coil.

19. The electromagnetic component of claim 1, wherein the component has a height dimension of less than about 5 mm.

20. The electromagnetic component of claim 1, wherein the component is a power inductor.
